(19) United States
(12) Patent Application Publication
(10) Pub. No.: US 2011/0155239 A1
(43) Pub. Date: Jun. 30, 2011

(54) SOLAR CELL AND METHOD FOR THE PRODUCTION THEREOF

(75) Inventors: Daniel Biro, Freiburg (DE); Florian Clement, Freiburg (DE); Oliver Schultz-Wittmann, Sunnyvale, CA (US)

(73) Assignee: Fraunhofer-Gesellschaft Zur Forderung Der Angewandten Forschung E.V., Munchen (DE)

(21) Appl. No.: 12/997,623

(22) PCT Filed: May 29, 2009
(86) PCT No.: PCT/EP09/03859

§ 371 Date: Mar. 11, 2011

(30) Foreign Application Priority Data
Jun. 11, 2008 (DE) 102008027780.0

(51) Int. Cl. H01L 31/0216; H01L 31/18

(52) U.S. Cl. 136/256; 438/98; 257/E31.124

(57) ABSTRACT

A solar cell having a semiconductor substrate with a front face and a rear face extending substantially parallel thereto, a front face metallization, a rear face metallization and at least three doped regions having at least two different conductivity types, including: a first doped region with a first conductivity type located on the front face of the semiconductor substrate and extends substantially over the entire front face; a second doped region with the opposite conductivity type to that of the first conductivity type located on the rear face and extends partially over said face; and a third doped region with the first conductivity type located on the rear face and extends partially over said face. The front face metallization is connected to the first doped region and the rear face metallization is connected to the second doped region in an electrically conductive manner and the solar cell has an electrically conductive connection which connects the third doped region to the front face metallization and/or the first doped region.

### BACKGROUND

The invention relates to a solar cell as well as to a method for the production of this solar cell.

In the case of a solar cell, positive and negative charges (electrons and the holes corresponding to these electrons) are separated by incident electromagnetic radiation and fed to two contact points separated from each other, so that electrical power can be picked up by an external circuit.

Typically, the semiconductor substrate consists of a flat silicon wafer that features p-doping. This p-doped region is also named base. In the base, the holes represent majority charge carriers and the electrons represent minority charge carriers.

A typical solar cell features, on the front side of the silicon wafer, an n-doped region, the emitter. Between the emitter and the rest of the p-doped substrate (the base), a pn junction is created at which the charge carriers are separated. In the emitter, the electrons represent the majority and the holes represent the minority.

Typical solar cells feature, on the front side, a lattice-shaped metallization and, on the rear side, a full-surface-area metallization. The front-side metallization is connected in an electrically conductive manner to the emitter, so that the electrons in the emitter can be led via the front-side metallization into the external circuit. Likewise, the rear-side metallization is connected in an electrically conductive manner to the p-doped region of the solar cell, so that the holes can be led via the rear-side metallization likewise into the external circuit.

The front-side metallization features at least one contact face that has a sufficient size, so that, by means of a cell binder, the front-side metallization can be connected in an electrically conductive manner to another solar cell or to the external circuit.

For the typical use of a solar cell for generating electrical energy, several solar cells are connected to each other in one solar-cell module. Here, the connection is typically realized in series, i.e., the rear-side metallization of one solar cell is connected in an electrically conductive manner to the front-side metallization of an adjacent solar cell.

To increase the efficiency of the solar cell, it is known to also cover the rear side of the solar cell partially by an n-doped rear-side emitter. This is because, in this way, electrons that are generated in the doped region or close to the rear side of the solar cell can also be collected by the rear-side emitter and the likelihood that the electrons recombine with holes and therefore do not contribute to electrical energy that can be picked up from the outside is reduced (see, e.g., U.S. Pat. No. 5,468,652).

Solar cells are known in which both the emitter of the front side and also the emitter of the rear side feature metallization, wherein, on the rear side, a comb-like metallization of the p-doped region and a comb-like metallization of the rear-side emitter doped region mesh with each other. The front-side and rear-side metallization regions of the emitter are connected to each other in an electrically conductive manner by holes in the solar cell filled with a metallization. For these solar cells, the rear side features, on one hand, contact faces of the p-metallization, as well as contact faces of the n-metallization, so that the entire contacting of the solar cell takes place on the rear side.

In this way, however, disadvantages are produced in the use of this solar cell in standard modules, because complicated methods are necessary for contacting and connecting the individual solar cells in the module.

### SUMMARY

Starting from here, the objective of the present invention is to provide a solar cell that increases, for one, the efficiency relative to the conventional solar-cell structure and simultaneously allows a simple and thus economical connection in the module.

This objective is met by a solar cell as well as a method according to the invention. Advantageous constructions as well as a solar-cell module are described below. Advantageous constructions of the method are also described below.

The solar cell according to the invention thus comprises a semiconductor substrate with a front side and a rear side essentially parallel to this front side, as well as a front-side metallization and a rear-side metallization.

The solar cell further has at least three doped regions with at least two different conductivity types:

First, on the front side of the semiconductor substrate, a first doped region of a first conductivity type is arranged that extends essentially across the entire front side of the semiconductor substrate.

On the rear side of the semiconductor substrate there is a second doped region of a second conductivity type that is opposite the first type, with this second region extending partially across the rear side. Furthermore, the rear side is partially covered by a third doped region of the first conductivity type.

The conductivity type of a doped region is given by the p-doping or the n-doping opposite the p-doping.

Furthermore, the front-side metallization is connected to the first doped region and the rear-side metallization is connected to the second doped region in an electrically conductive manner, so that charge carriers from the first doped region can be picked up via the front-side metallization and charge carriers from the second doped region can be picked up via the rear-side metallization.

The solar cell further comprises an electrically conductive connection that connects the front-side metallization and/or the first doped region in an electrically conductive manner to the third doped region. Thus, charge carriers can be led from the third doped region directly or via the first doped region to the front-side metallization and picked up there.

It is essential that both the front-side metallization comprises at least one front-side contact face and also the rear-side metallization comprises at least one rear-side contact face, wherein the contact faces are each at least 0.5 mm long and at least 0.5 mm wide. The contact faces are arranged approximately parallel to the corresponding side of the semiconductor substrate.

In this way, both the front-side metallization and also the rear-side metallization can be contacted with conventional contacting methods, in particular, can be connected electrically with conventional cell connectors.

The solar cell according to the invention further distinguishes itself in that the contact faces lie on a common imaginary plane extending perpendicular to the rear side of the substrate. With the rear side of the solar cell, this plane forms an imaginary rear-side section boundary and the solar cell according to the invention is constructed such that there is no electrical connection to the third doped region and no electrical connection to the first doped region along this imaginary rear-side section boundary, as well as no electrical connection to the front-side metallization.

Through this configuration of the solar cell according to the invention, it is possible to guide an essentially linear cell connector along the imaginary rear-side section boundary on the rear side of the solar cell. This cell connector is in electrically conductive connection only with the contact face of the rear-side metallization due to the configuration of the solar cell according to the invention and is, in particular, not connected in an electrically conductive manner to the third doped region, the first doped region, and the front-side metallization.

Likewise, an essentially linear cell connector could be arranged on a front side along an imaginary front-side section boundary between the imaginary plane and the front side of the solar cell. This cell connector stands in electrically conductive connection only with the front-side metallization via its front-side contact face due to the configuration of the solar cell according to the invention and runs parallel to the rear-side cell connector.

In this way, the solar cell according to the invention can be connected in a standard solar cell module in the same way, like a conventional solar cell that has only one emitter on the front side.

Therefore, however, because the solar cell according to the invention has a first and also at least one third doped region of the first conductivity type, wherein the third doped region is arranged on the rear side of the solar cell, the efficiency of the solar cell according to the invention increases relative to the conventional solar cell.

For the typical solar cell described above, the n-doped emitter on the front side represents the first doped region, the p-doped base (that thus has a conductivity type opposite that of the emitter) represents the second doped region, and the n-doped rear-side emitter represents the third doped region. Likewise, however, the transposition of the n-doping and the p-doping also lies in the scope of the invention.

Studies of the applicant have shown that, for certain contacting methods of the contact faces, a greater surface area is advantageous. Advantageously, the front-side contact face and/or rear-side contact face are therefore at least 0.5 mm long and at least 0.5 mm wide, in particular, at least 1 mm long and 1 mm wide, most particularly, at least 1.5 mm long and 1.5 mm wide.

Advantageously, the solar cell according to the invention is constructed such that the rear side of the solar cell is covered along the rear-side section boundary with a doped region of the second conductivity type. In this way it is possible to guide the rear-side metallization like a line along the rear-side section boundary, so that charge carriers can be collected along this boundary and fed to the contact face of the rear-side metallization lying on the rear-side section boundary.

In another advantageous construction, the rear side of the solar cell is covered with an insulating layer along the rear-side section boundary and outside of the contact face.

A cell connector guided on the rear side of the solar cell along the rear-side section boundary is thus in electrical connection with the rear-side metallization only on the contact face. This has the advantage that the recombination on the rear side can be reduced.

It is essential that the solar cell is constructed such that a cell connector guided on the rear-side section boundary on the rear side of the solar cell has no electrical connection to the first and third doped regions, as well as to the front-side metallization. This can be guaranteed, as described above, such that the rear-side metallization is guided along the entire rear-side section boundary or such that only the rear-side metallization or the second doped region is arranged along the rear-side section boundary. Likewise it is possible that the solar cell has, on the rear side in the region of the rear-side section boundary, at least partially an insulating layer, so that a cell connector constructed on the rear side of the solar cell along the rear-side section boundary has no electrical connection to doped regions arranged under the insulating layer.

Furthermore, it is advantageous that the contact face of the front-side metallization extends essentially across the entire width of the solar cell, so that charge carriers from the first doped region can enter into the front-side metallization across the entire width of the solar cell and are led within the front-side metallization to the contact face of the front-side metallization.

In another advantageous configuration, the front-side metallization and/or the rear-side metallization comprise several contact faces that lie on the common section face standing perpendicular to the front side.

A cell connector guided on the rear side along the rear-side section boundary or a cell connector guided on the front side along the front-side section boundary is thus in electrically conductive connection with several contacting faces, so that losses can be reduced due to the shunt-conductance resistance in the metallization.

Advantageously, the contact face is arranged on the front side across the contact face of the rear side, so that front-side and rear-side cell connectors are connected at the same position of the front side and rear side and thus the resulting pressure during the bonding is compensated.

Advantageously, the solar cell according to the invention is constructed as a p-silicon solar cell, i.e., the semiconductor substrate is a p-doped silicon wafer and the first and the third doped regions represent n-doped emitters.

Here it is advantageous if the first doped region is constructed as a low-impedance emitter in the doped region 20 Ohm/sq to 70 Ohm/sq and the third doped region is constructed as a high-impedance emitter in the doped region 70 Ohm/sq to 130 Ohm/sq, so that studies of the invention have shown that, in this way, first, the lowest possible losses exist due to shunt-conductance resistance in the emitter and, second, low losses exist due to the contact resistance to the front-side metallization and thus the efficiency of the solar cell can be optimized.

In particular, it is advantageous if the first doped region is constructed approximately as a 50 Ohm/sq emitter and the third doped region as an emitter in the doped region 80 Ohm/sq to 100 Ohm/sq.

In another advantageous configuration, the front-side metallization is constructed as a standard contact lattice. This comprises several linear metallization fingers that are arranged essentially parallel and each have a width in the range of 30 μm to 200 μm. These metallization fingers are connected to each other by a busbar that is perpendicular to the fingers and is constructed as a contacting face, i.e., has at least a width of 1.5 mm and covers approximately the entire front side of the solar cell with respect to its length. The busbar is connected in a conductive manner to the metallization fingers, so that charge carriers that are collected by the metallization fingers can be picked up on the busbar.

In another advantageous configuration, the solar cell according to the invention has, on its rear side, several island-like doped regions of the first conductivity type, with these regions being separated from each other by at least one doped region of the second conductivity type.

Each of these island-like doped regions is connected in a conductive manner to the front-side metallization, so that charge carriers of the island-like doped regions can be picked up via the contacting face of the front-side metallization.

Here it is especially advantageous if each island-like doped region of the first conductivity type has a metallization connected in a conductive manner to this doped region. This metallization is connected, in turn, in a conductive manner to the front-side metallization. The charge carriers collected by the island-like doped regions can thus be entered into the metallization of this island-like doped region and then led within the metallization to the contacting face of the front-side metallization and picked up there. In this way, the series resistance is reduced, so that the efficiency of the solar cell can be increased.

Advantageously, the metallization of the island-like doped regions is constructed as metallization fingers that have a width in the doped region of 30 to 200 μm.

In another advantageous configuration, the rear-side metallization is constructed as a standard contact lattice that comprises, as previously described, several linear metallization fingers arranged essentially parallel with a width in the range of 30 to 200 μm. Furthermore, the rear-side metallization has a contacting face that is constructed as a busbar and is essentially perpendicular to the metallization fingers and connects these to each other in an electrically conductive manner.

This shape of the rear-side metallization has the advantage that the island-like doped regions of the first conductivity type can be arranged between the metallization fingers and the busbar on the rear side, so that the island-like doped regions engage like a comb in the rear-side metallization and thus also in the doped regions of the second conductivity type on the rear side of the solar cell.

In this way, a high efficiency of the solar cell can be achieved, because the island-like doped regions achieve a high efficiency in the collection of charge carriers due to the comb-like covering of the rear side.

In one advantageous configuration, the solar cell has recesses that are essentially perpendicular to the front side of the solar cell and penetrate both the first and also the third doped regions, wherein the first and the third doped regions are connected in an electrically conductive manner by the recesses. These recesses can be constructed, for example, as holes, i.e., essentially cylindrical or block-shaped recesses.

The electrical connection between the first and third doped regions can be guaranteed advantageously such that the recess has at least partially a doped region of the first conductivity type on the walls, with this region being arranged such that it connects the first and the third doped regions in an electrically conductive manner.

Thus, in this advantageous embodiment, charge carriers from a third doped region on the rear side can be led via the walls of the recess to the first doped region on the front side and enter there into the front-side metallization.

Likewise it is also advantageous that the recesses have at least partially one metallization that connects the first and the third doped regions in an electrically conductive manner. In this case, charge carriers can enter from the third doped region into the metallization in the recess and can be led via this metallization to the front-side metallization.

Conventional solar cells typically have a full-surface-area rear-side metallization. This also represents, in addition to its function as rear-side contacting, an optical mirror that reflects electromagnetic radiation penetrating from the front side, so that the radiation absorbed in the solar cell can be increased.

For the solar cell according to the invention, there is no full-surface-area covering of the rear side by the rear-side metallization. Advantageously, the solar cell according to the invention therefore has an optical mirror that covers the rear side of the solar cell, so that radiation incident via the front side into the solar cell is reflected and therefore the absorption in the solar cell is increased. Advantageously, the mirror is constructed as an aluminum layer.

As previously mentioned, the solar cell according to the invention has the advantage that it can be connected like a kind of standard solar cell in one module. In one advantageous embodiment, a solar-cell module is constructed with solar cells according to the invention such that at least two solar cells are arranged one next to the other, wherein at least one cell connector connects the rear-side metallization of the first solar cell to the front-side metallization of the second solar cell.

The solar-cell connector is here constructed such that it runs essentially in a straight line when viewed from above.

Advantageously, the semiconductor substrate has a flat shape like, for example, a silicon wafer. The front and rear sides of a solar cell are typically essentially planar, wherein slight structuring for texturing, i.e., improving the optical properties of the front or rear side of the solar cell or structuring for limiting the doped regions can be advantageous. Typically, the thickness of the semiconductor substrate lies in the range of 50 μm to 300 μm, wherein the texturing and structuring typically have height differences of less than 15 μm on the front or rear side of the solar cell.

Advantageously, the semiconductor substrate essentially has a block-shaped construction and the imaginary plane is parallel to an end face of the semiconductor substrate.

The previously described solar cell according to the invention further has the advantage that it can be produced essentially with a standard production method. The basic objective is therefore likewise solved by a method according to claim 20 that comprises the following processing steps (here the numbering refers to the embodiment already described in FIG. 8):

In the method according to the invention, in a step b-2, the cutting damage is removed from a semiconductor wafer with a front side and a rear side essentially parallel to this front side.

Then, in a step b-4, a first doped region of a first conductivity type is diffused. The first doped region extends essentially across the entire front side of the semiconductor wafer and thus of the later solar cell. Furthermore, at least one third doped region of the first conductivity type is diffused, wherein the third doped region extends partially across the rear side of the solar cell.

In a step b-7, a rear-side metallization is deposited that partially covers the rear side and accordingly, in a step b-8, a front-side metallization is deposited that partially covers the front side.

It is essential that in the previously described step b-7, the rear-side metallization only partially covers the rear side and that, for the deposition of the front side, a front-side contact face lying approximately parallel to the front side is constructed and, for the rear side, a rear-side contact face lying approximately parallel to the rear side is constructed. The front-side and rear-side contact faces are each at least 0.5 mm long and 0.5 mm wide and the front-side and rear-side contact faces are arranged such that they are penetrated by a common imaginary plane standing perpendicular to the rear side.

The solar cell is further constructed such that, on the rear side of the solar cell, there is no electrical connection to the third doped region and no electrical connection to the first doped region along an imaginary rear-side section boundary between the rear side of the solar cell and the imaginary plane.

In this way it is guaranteed that an electrically conductive cell connector guided along the rear-side section boundary on the rear side of the solar cell is connected in an electrically conductive manner only to the rear-side metallization and/or to the second doped region.

Advantageously, for the method according to the invention, a doped region of the second conductivity type is constructed on the rear side of the solar cell along the rear-side section boundary.

In another advantageous construction of the method according to the invention, the rear side is covered with an insulating layer on the rear side of the solar cell along the rear-side section boundary and outside of the rear-side contact face.

For connecting the first and third doped regions it is advantageous that holes are generated in the solar cell in a step b-1, with these holes standing essentially perpendicular to the front side of the solar cell. In particular, it is advantageous to generate these holes using a laser, because in this way a precise-position and fast generation of the holes is possible.

In another advantageous construction of the method, in a step b-4, in addition to the hole walls, a doped region of the first conductivity type is generated and the third doped region is arranged in the region of the holes, so that the first and third doped regions are connected to each other in an electrically conductive manner by the doped region on the hole walls.

### BRIEF DESCRIPTION OF THE DRAWINGS

Additional advantageous constructions will be explained in detail below with reference to the embodiments shown in the figures. Shown herein are:

FIG. 1 the front side of a solar cell according to the invention in schematic representation,

FIG. 2 the rear side of the solar cell according to the invention in schematic representation,

FIG. 3 a section diagram along the line designated with I in FIG. 1 and FIG. 2, wherein the section plane extending perpendicular to the plane of the drawing in FIG. 1 and in FIG. 2,

FIG. 4 a section diagram along the line designated with II in FIG. 1 and FIG. 2, wherein here the section plane also extends perpendicular to the plane of the drawing in FIG. 1 and in FIG. 2,

FIG. 5 several solar cells according to the invention connected with cell connectors in series in plan view from above,

FIG. 6 several solar cells according to the invention connected with cell connectors in series in plan view from below, and

FIG. 7 a section diagram through the solar cells connected with cell connectors and shown in FIG. 5 and in FIG. 6, wherein the section plane extends perpendicular to the plane of the drawing in FIG. 5 and in FIG. 6 and runs approximately in the middle through the line formed by the cell connectors, and

FIG. 8 a comparison of a production method for a solar cell according to the prior art and a solar cell according to the invention.

### DETAILED DESCRIPTION OF THE PREFERRED EMBODIMENTS

The semiconductor substrate of the solar cell according to the invention and shown in the figures is a block-shaped silicon wafer whose length and width equal approximately 12 cm and has a thickness of approximately 250 μm.

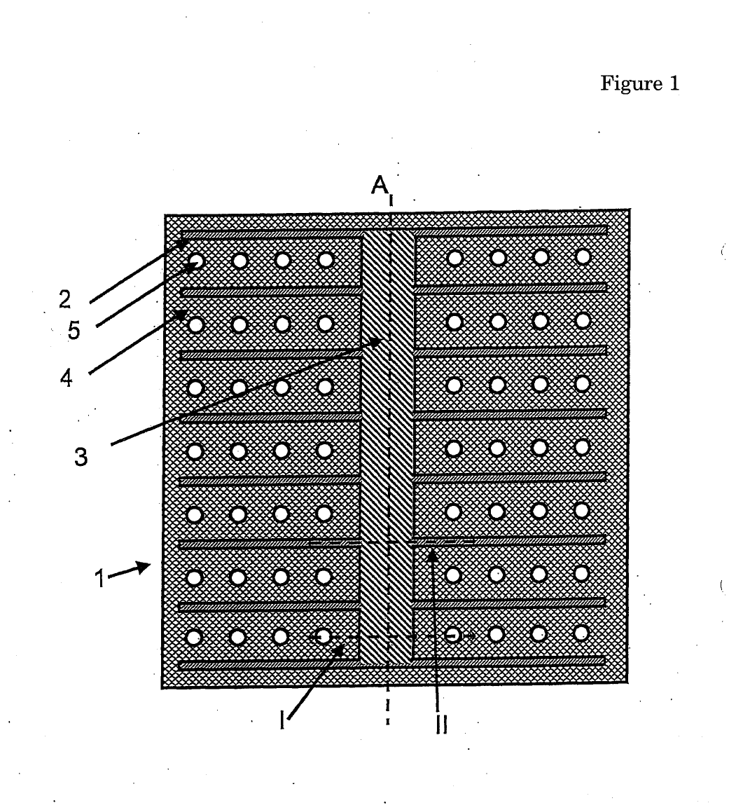

As can be seen in FIG. 1, on the front side of the silicon wafer 1, a double-comb-like front-side metallization 2 is deposited. The front-side metallization 2 comprises a front-side busbar 3 that is arranged in the middle and starting from which extend comparatively narrower metallization strips, the so-called fingers, across the surface of the solar cell.

The front side of the silicon wafer 1 is covered completely by an n-doped region, the front-side emitter 4, shown in FIG. 1 with diagonal cross-hatching. The front-side emitter 4 thus represents the first doped region.

Furthermore, the silicon wafer 1 is penetrated by several essentially cylindrical holes 5.

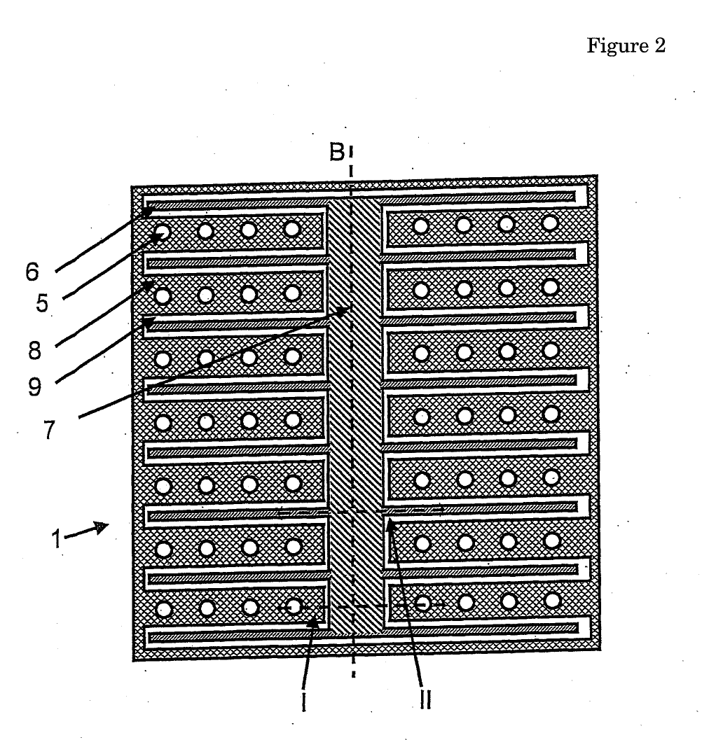

As can be seen in the rear-side view of the solar cell according to the invention shown in FIG. 2, the rear-size metallization 6 is arranged on the rear side of the silicon wafer 1, with this rear-side metallization likewise having a double-comb-like construction and comprising a middle rear-side busbar 7 from which the fingers of the rear-side metallization extends across the rear side of the silicon wafer 1.

The rear side also has an n-doped region, the rear-side emitter 8 shown in FIG. 2 with diagonal cross-hatching, which partially covers the rear side, in particular, in the region of the holes 5. The rear-side emitter 8 thus represents the third doped region.

The silicon wafer 1 has a p-base doping, i.e., it is p-doped outside of the emitter regions. This p-doped region thus represents the base of the solar cell according to the invention. As can be seen in FIG. 2, the rear side of the silicon wafer 1 is not covered by the rear-side emitter 8 in the region of the rear-side metallization 6, so that the rear-side metallization 6 lies directly on the base 9 and is connected to this in an electrically conductive manner. The base 9 thus represents the second doped region.

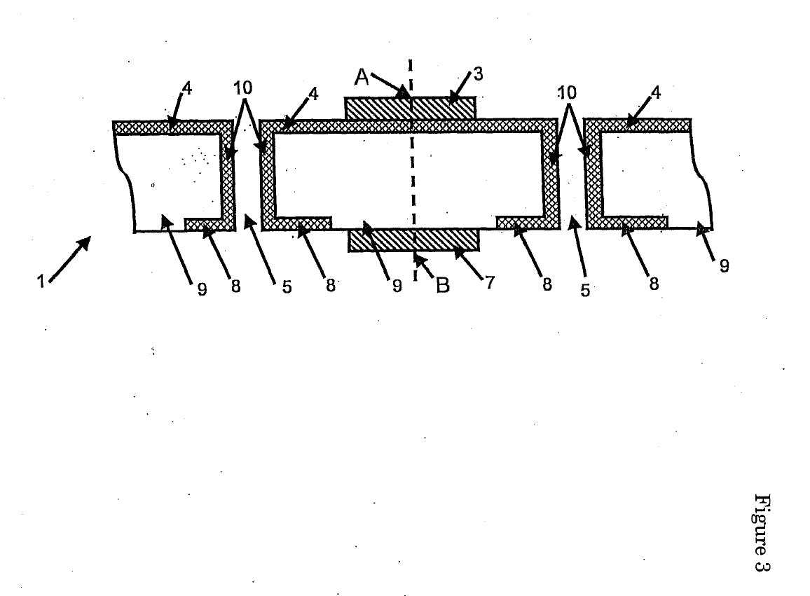

FIG. 3 represents a cross section perpendicular to the plane of the drawing in FIG. 1 and FIG. 2 on the line indicated with I and drawn as a dashed line.

For the silicon wafer 1 penetrated by the holes 5, the front-side emitter 4 that covers the entire front side is arranged on the front side. The rear side of the silicon wafer 1 is covered partially by the rear-side emitter 8 and partially by the base 9. A connection emitter 10 is arranged on the walls of the holes 5, so that the rear-side emitter 8 is connected in an electrically conductive manner to the front-side emitter 4 by the connection emitter 10.

It would likewise be possible to provide, alternatively or additionally, a connection metallization in the holes 5 that connects the rear-side emitter 8 in an electrically conductive manner to the front-side emitter 4 and/or to the front-side metallization 2.

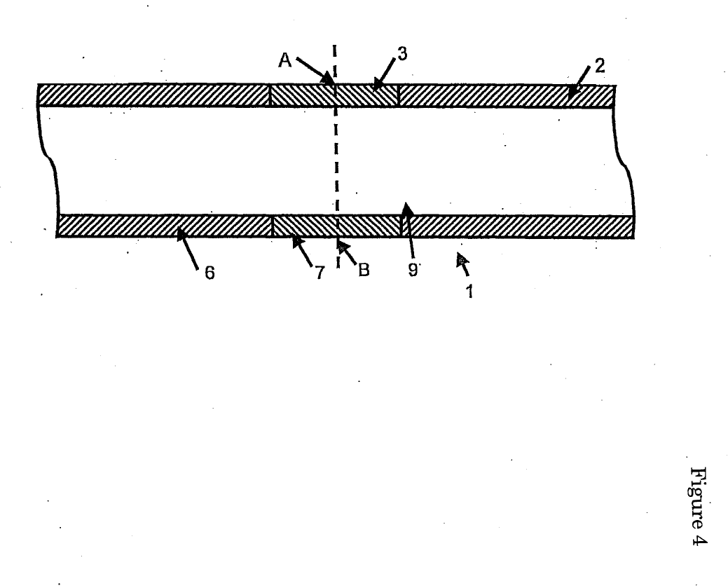

FIG. 4 shows a section along the line indicated with II in FIGS. 1 and 2 and drawn as a dashed line, wherein the section plane lies perpendicular to the plane of the drawing in FIG. 1 and FIG. 2. In the section region designated with II, there is no emitter, but instead the base 9 extends from the front-side metallization 2 with front-side busbar 3 arranged in the middle up to the rear-side metallization 6 with rear-side busbar 7 arranged in the middle.

Now it is essential that the front-side metallization and the rear-side metallization each comprise a contact face, wherein the contact face is at least 0.5 mm long and at least 0.5 mm wide.

These contact faces are realized in the embodiment shown in the figures by the front-side busbar 3 and the rear-side busbar 7. The front-side and rear-side busbars have a width of 2 mm and a length of approximately 11 cm. Thus they have a sufficient surface area, in order to be connected to a cell connector.

Front-side and rear-side busbars are penetrated by a common imaginary plane that extends perpendicular to the rear side of the silicon wafer 1.

This imaginary plane is shown in FIGS. 1 to 4 each by a dashed line in the middle, wherein the imaginary plane extends perpendicular to the plane of the drawing in each of the FIGS. 1 to 4.

On the front side of the solar cell, the front-side busbar 3 represents the highest raised section in the region of the imaginary plane, so that the section boundary of the top side of the front-side busbar 3 represents the front-side section boundary with the imaginary plane. This section boundary is drawn as a dashed line in FIG. 1 and designated with A, wherein, on the uppermost and lowermost edges of the solar cell, there is no front-side metallization and the front-side section boundary A in this region is thus the section boundary between the front side of the silicon wafer 1 and the imaginary plane.

Analogously, on the rear side of the solar cell, the rear-side busbar 7 represents the highest raised section in the region of the imaginary plane, so that the section boundary between the bottom side of the rear-side busbar 7 and the imaginary plane represents the rear-side section boundary that is drawn in FIG. 2 by the dashed line designated with B. Also, on the rear side there is, in the uppermost and lowermost edges, no rear-side metallization, so that, in this region, the rear-side section boundary runs along the rear-side emitter 8, i.e., on the rear side of the silicon wafer 1.

Accordingly, the position of the front-side section boundary A and rear-side section boundary B is shown in FIGS. 3 and 4, wherein the section boundaries extend perpendicular to the plane of the drawing in each of these figures.

On the rear side of the silicon wafer 1, the silicon wafer 1 is covered by a (not shown) silicon-dioxide layer in the regions that are covered by the rear-side emitter 8, wherein this silicon-dioxide layer has a thickness of approximately 10 nm. This “native” silicon-dioxide layer is created by oxidation with ambient oxygen and therefore does not have to be created by a separate processing step. The silicon-dioxide layer is insulating, so that there is insulation for the rear-side emitter 8 by the silicon-dioxide layer along the rear-side section boundary B in the regions that are not covered by the rear-side metallization. Likewise, it is conceivable to deposit an insulating layer in these regions in a separate processing step.

Thus there is no electrical connection to the rear-side emitter 8, the front-side emitter 4, the connection emitter 10, or the front-side metallization 2 along the entire rear-side section boundary B.

Through this construction, the solar cell according to the invention shown in this embodiment could be connected in a module with a standard wiring method.

As already explained above, solar cells are typically connected in series in the module by cell connectors, in that the electrically conductive cell connector connects the front-side metallization of a solar cell to the rear-side metallization of an adjacent solar cell.

Here it is essential that the cell connectors have an essentially straight-line construction, so that for solar cells arranged next to each other like a row, the front-side contact face and the rear-side contact faces of the solar cells must be arranged such that they are penetrated by a common imaginary plane standing perpendicular to the rear side, so that the cell connector on one cell can be guided, for example, along the front-side section boundary and on the adjacent cell along the rear-side section boundary.

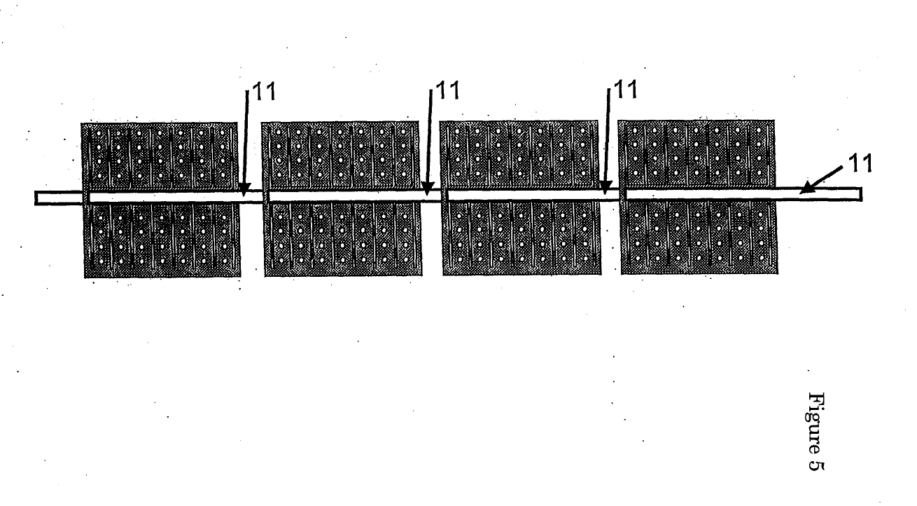

This wiring principle is shown in FIGS. 5 to 7.

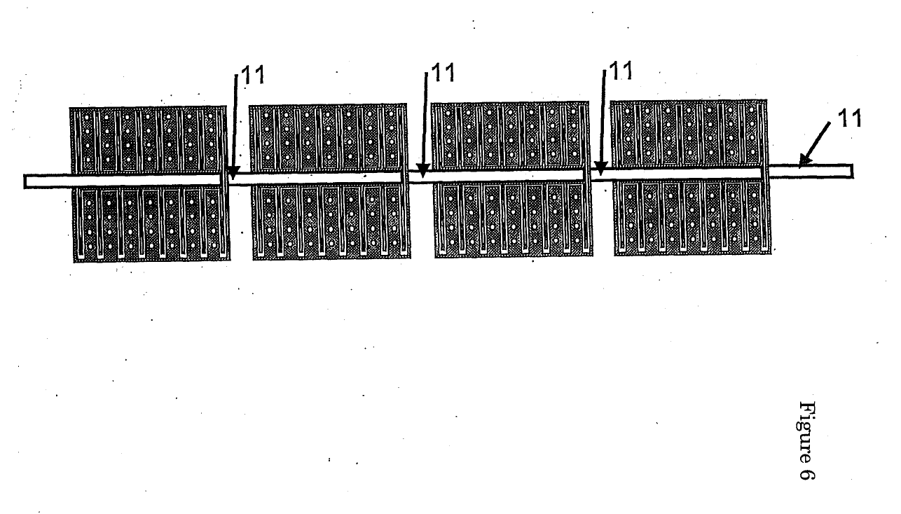

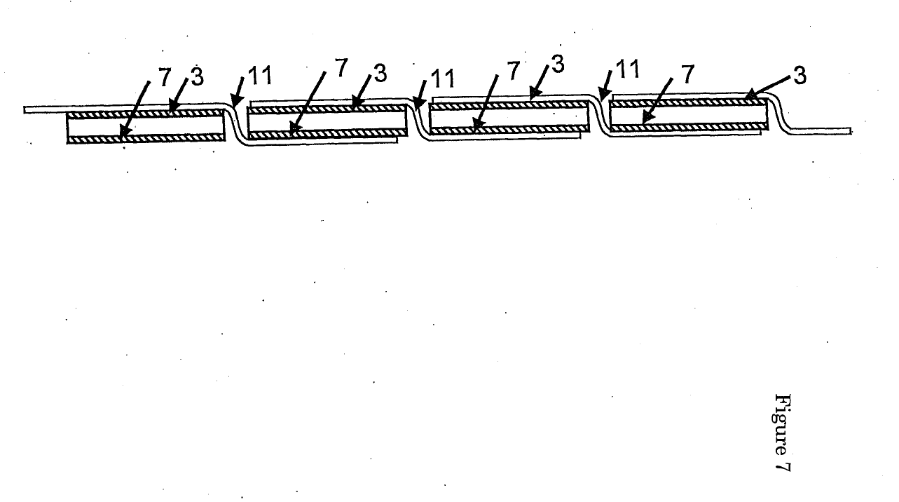

In FIG. 5, four solar cells according to the invention are arranged one next to the other like a row, wherein each solar cell is connected in an electrically conductive manner to the adjacent solar cell by a cell connector 11. As shown in the section drawing in FIG. 7, the cell connector 11 connects the rear-side busbar 7 of one solar cell to the front-side busbar 3 of an adjacent solar cell. Through the arrangement of front-side and rear-side busbars for the solar cell according to the invention, the cell connector can be guided here like a line, i.e., in plan view from above as shown in FIG. 5, the cell connector 11 extends like a line from the front side of one solar cell to the rear side of the next solar cell. Likewise, the linear course of the cell connector 11 can be seen in FIG. 6 in the view from below of the solar cells according to the invention connected in series.

This type of wiring by a cell connector guided in a line in a plan view from above represents a standard method in the module wiring. In particular, it is advantageous when the cell connector essentially covers the entire width of the solar cell, so that the smallest possible contact resistance between the cell connector 11 and front-side busbar 3 or rear-side busbar 7 is allowed due to the large contact face and, in addition, the shunt-conductance resistance of the front-side and rear-side busbars is also reduced by the parallel cell connectors 11, so that overall power losses due to ohmic resistance are minimized.

The solar cell according to the invention thus combines the advantages that it can be wired with a standard method in the module and also that charge carriers on the front side can be collected by the first doped region (the front-side emitter 4 of the embodiment) and charge carriers can be collected on the rear side by the third doped region (the rear-side emitter 8 of the embodiment).

Another advantage of the solar cell according to the invention is that is can be produced with the standard processing steps of the production of a typical industrial solar cell, wherein only slight modifications are necessary.

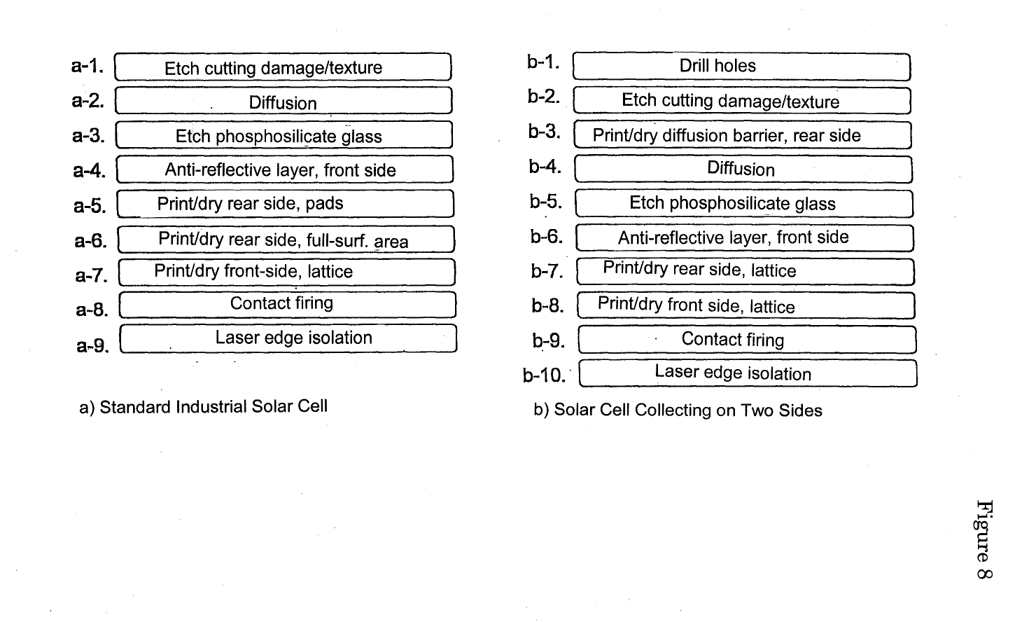

In FIG. 8, in the left column (a), the sequence for the production of a conventional industrial solar cell is shown. Such an industrial solar cell has, on the front side, an emitter, with the rest of the semiconductor substrate representing the base. The emitter is contacted by a front-side metallization deposited on the front side and the base is contacted by a rear-side metallization deposited on the rear side.

For the production, initially in step a-1 the cutting damage of the semiconductor is removed and a texture is applied to the front side, in order to increase the energy output of the solar cell. The semiconductor wafer is here provided typically homogeneously with p-doping.

In a diffusion step a-2, the emitter is diffused on the front side of the semiconductor wafer provided with a texture.

For these processing steps, phosphosilicate glass is created that is etched in a step a-3.

In order to further increase the energy output of the solar cell, in a step a-4, an anti-reflective layer is deposited on the front side. This could be, for example, a single-layer silicon-dioxide layer or a silicon-nitride layer, but multi-layer anti-reflective layers are also known.

In the steps a-5 to a-7, using printing methods, the front-side and rear-side metallization regions are deposited.

In a standard method, here, initially in a step a-5, the so-called “pads,” i.e., the contacting faces are printed on the rear side and after drying of these contacting faces, the rear side is metallized across the whole surface in a step a-6.

In this way, in a step a-7, the front-side metallization is printed in the form of a comb-like metallization lattice described above. The sequence of printing steps here could also be transposed.

Due to the effect of heat, it is achieved that the printed metallization regions form an electrical contact to the underlying doped regions. This is also named “contact firing” and is shown in FIG. 8 as step a-8.

In order to prevent electrical short circuits and damage typically occurring at the edges of the semiconductor wafer, in a step a-9 a laser edge isolation process is performed, i.e., a thin, peripheral edge region of the semiconductor wafer is separated electrically from the rest of the solar cell by the effect of a laser, so that also in this edge region, possible short circuits or other damage to the semiconductor structure have no or only negligibly small effect on the electrical properties of the solar cell. Likewise it is possible to perform the laser edge isolation process directly after the diffusion, in particular, directly after step a-2 (or b-4 in the method according to the invention). Advantageously, the laser edge isolation process is performed starting from the front side.

As can be seen in the right column designated with (b) in FIG. 8, the method shown as an example in FIG. 8 for the production of a solar cell according to the invention has only one processing step more than the method for the production of the known solar cell:

In an additional step b-1, at the beginning before the removal of the cutting damage, the recesses are generated in the semiconductor wafer, wherein these recesses allow an electrical connection of the first and third doped regions. These holes in the semiconductor wafer, which penetrate the semiconductor wafer approximately perpendicular to the front side and rear side, are created advantageously using a laser, i.e., by the effect of heat from the laser evaporating the semiconductor material a few positions, so that the solar cell obtains holes as shown, for example, in FIGS. 1 and 2.

The processing step designated with b-3 represents another additional step. Here, on the rear side, a so-called diffusion barrier is printed. This is used to separate the doped regions nested one in the other like a comb on the rear side (see FIG. 2) electrically from each other. The diffusion barrier thus runs approximately along the limits visible in FIG. 2 between the second and third doped regions.

Advantageously, a diffusion barrier is also deposited on the rear side in the region of the edges, in particular, simultaneously with the diffusion barrier in processing step b-3, so that no additional processing step is required. Through this diffusion barrier, the edge isolation is no longer necessary, so that processing step b-10 can be eliminated.

Because only one metallization in the form of a comb-like lattice is deposited on the front and rear sides of the solar cells, the processing steps shown for the standard industrial solar cell as processing steps a-5 to a-7 can be realized by only two processing steps b-7 to b-8, i.e., on one hand, printing and drying of the rear-side lattice and, on the other hand, printing and drying of the front-side lattice. Likewise, it lies in the scope of the invention to deposit front-side and/or rear-side lattices in multi-stage printing steps.

As an alternative to the previously described deposition of a diffusion barrier in the processing step b-3, it is also possible to leave out the step b-3 and instead to perform, after the diffusion (processing step b-4) an electrical separation between the second and third doped regions on the rear side of the solar cell by a laser. For this purpose, a laser beam is guided on the rear side of the solar cell along the edge of the third doped region, so that due to the effect of heat, electrical isolation between the second and third doped regions is achieved. Advantageously, this is performed in step b-10 with simultaneous edge isolation.

The designation “electrically conductive connection” in the preceding description excludes currents that can flow under certain conditions across the pn junction of the solar cell or that can be generated by recombination effects at the pn junction.

In the sense of this description, the front-side metallization is connected in an electrically conductive manner to the first and third doped regions, but not with the second doped region or the rear-side metallization, because here the majority charge carriers in the first and third doped regions must overcome the pn junction. Likewise the second doped region is not connected in an electrically conductive manner to the first and second doped regions or the front-side metallization, because here the majority charge carriers in the second doped region must overcome the pn junction.

1. Solar cell, comprising
a semiconductor substrate with a front side and a rear side essentially parallel to the front side,
a front-side metallization (2) and a rear-side metallization (6), and
at least three doped regions with at least two different conductivity types, including:
on the front side of the semiconductor substrate there is a first doped region of a first conductivity type extending essentially across an entire area of the front side,
on the rear side of the semiconductor substrate there is a second doped region of a second conductivity type that is opposite the first conductivity type, with the second doped region extending partially across the rear side, and
on the rear side there is a third doped region of the first conductivity type extending partially across the rear side,
wherein the front-side metallization (2) is connected in an electrically conductive manner to the first doped region and the rear-side metallization (6) is connected in an electrically conductive manner to the second doped region, and
the solar cell has an electrically conductive connection that connects, in an electrically conductive manner, the third doped region to at least one of the front-side metallization (2) or to the first doped region,
the front-side metallization (2) comprises at least one front-side contact face lying approximately parallel to the front side, and the rear-side metallization (6) comprises at least one rear-side contact face lying approximately parallel to the rear side and the front-side contact face and the rear-side contact face are each at least 0.5 mm long and at least 0.5 mm wide,
the front-side and the rear-side contact faces are arranged such that they are penetrated by a common imaginary plane extending perpendicular to the rear side, and
the solar cell is constructed such that, on the rear side of the solar cell, there is no electrical connection to the third doped region and no electrical connection to the first doped region along an imaginary rear-side section boundary between the rear side of the solar cell and the imaginary plane, such that an electrically conductive cell connector (11) guided along a rear-side section boundary on the rear side of the solar cell is connected in an electrically conductive manner only to at least one of the rear-side metallization (6) or the second doped region.

2. Solar cell according to claim 1, wherein the rear side of the solar cell is covered along the rear-side section boundary with a region of the second conductivity type.

3. Solar cell according to claim 1, wherein the rear side of the solar cell is covered along the rear-side section boundary and outside of the contact face with an insulating layer.

4. Solar cell according to claim 1, wherein the contact face of the front-side metallization (2) extends essentially across an entire width of the solar cell.

5. Solar cell according to claim 1, wherein the front-side metallization (2) or the rear-side metallization (6) have several contact faces that lie on a common section face extending perpendicular to the front side.

6. Solar cell according to claim 5, wherein the contact face of the front side is arranged across from the contact face of the rear side.

7. Solar cell according to claim 1, wherein the semiconductor substrate is a p-doped silicon wafer (1) and the first and the third regions are constructed as n-doped emitters, wherein the first region is constructed as a low-impedance emitter in the range of 20 Ohm/sq to 70 Ohm/sq and the third region is constructed as a high-impedance emitter in the range of 70 Ohm/sq.

8. Solar cell according to claim 1, wherein the front-side metallization (2) is constructed as a standard-contact lattice, comprising several linear metallization fingers arranged essentially parallel with a width in a range of 30 μm to 200 μm, and comprising at least one contact face constructed as a busbar that is arranged essentially perpendicular to the metallization fingers such that the busbar connects the metallization fingers in an electrically conductive manner.

9. Solar cell according to claim 1, wherein the solar cell has, on the rear side, several island-like regions of the first conductivity type that are separated from each other by at least one region of the second conductivity type.

10. Solar cell according to claim 9, wherein each of the island-like regions of the first conductivity type has a metallization connected in an electrically conductive manner to said region, with the metallization constructed as metallization fingers with a width in a range of 30 μm to 200 μm.

11. Solar cell according to claim 10, wherein the rear-side metallization (6) is constructed as a standard contact lattice comprising several linear metallization fingers arranged essentially parallel with a width in the region of 30 μm to 200 μm and comprising at least one contact face constructed as a busbar that is arranged essentially perpendicular to the metallization fingers such that the busbar connects the metallization fingers in an electrically conductive manner, and the island-like regions of the first conductivity type are arranged between the metallization fingers and the busbar on the rear side.

12. Solar cell according to claim 1, wherein the solar cell has recesses that extend essentially perpendicular to the front side of the solar cell and penetrate both the first and also the third regions, and the first and the third regions are connected in an electrically conductive manner by the recess.

13. Solar cell according to claim 12, wherein the recesses have, at least partially, a region of the first conductivity type on walls thereof, with said region being arranged such that it connects the first and the third regions in an electrically conductive manner.

14. Solar cell according to claim 13, wherein the recesses have, at least partially, a metallization that connects the first and the third regions in an electrically conductive manner or increases a conductivity in the recess.

15. Solar cell according to claim 1, wherein the rear side of the solar cell is covered essentially by an optical mirror.

16. Solar cell according to claim 1, wherein the rear-side metallization (6) comprises an essentially linear rear-side busbar (7) and the rear-side busbar (7) lies approximately on an imaginary rear-side section boundary or the front-side metallization (2) comprises an essentially linear front-side busbar (3) and the front-side busbar (3) lies on an imaginary front-side section boundary between the front side of the solar cell and the imaginary plane.

17. Solar cell according to claim 16, wherein the second doped region is arranged such that it covers the rear side of the semiconductor substrate at least in the region of the imaginary rear-side section boundary.

18. Solar cell according to claim 17, wherein the semiconductor substrate has an essentially block-shaped construction and the imaginary plane is parallel to an end face of the semiconductor substrate.

19. Solar-cell module, comprising at least two solar cells each with a front-side (2) and a rear-side metallization (6) and at least one cell connector (11), wherein the solar cells are arranged in the module lying one next to the other and the cell connector (11) connects the rear-side metallization (6) of the first solar cell to the front-side metallization (2) of the second solar cell, wherein the cell connector (11) is constructed essentially in a straight line in a vertical section, the two solar cells are constructed according to claim 1 and are arranged one next to the other such that the cell connector (11) extends starting from the contact face of the rear-side metallization (6) of the first solar cell essentially in a straight line in vertical section to the contact face of the front side of the second solar cell and connects the two contact faces in an electrically conductive manner.

20. Method for the production of a solar cell made from a semiconductor wafer with a front-side and a rear side essentially parallel to this front side according to, comprising the following processing steps:
b-2 removal of cutting damage on the semiconductor wafer, b-4 diffusion of a first doped region of a first conductivity type, wherein the first doped region extends essentially across an entire front side of the solar cell, and diffusion of at least a third doped region of the first conductivity type, wherein the third doped region extends partially across the rear side of the solar cell, b-7 deposition of a rear-side metallization, b-8 deposition of a front-side metallization that partially covers the front side, wherein in step b-7, the rear-side metallization is deposited only partially covering the rear side, for the deposition of the front side, a front-side contact face lying approximately parallel to the front side is constructed and for the deposition of the rear side, a rear-side contact face lying approximately parallel to the rear side is constructed, wherein the front-side and rear-side contact faces are each at least 0.5 mm long and 0.5 mm wide, and the front-side and rear-side contact face are arranged such that they are penetrated by a common imaginary plane extending perpendicular to the rear side, and the solar cell is constructed such that, on the rear side of the solar cell, there is no electrical connection to the third doped region and no electrical connection to the first doped region along an imaginary rear-side section boundary between the rear side of the solar cell and the imaginary plane, such that an electrically conductive cell connector (11) guided along the rear-side section boundary on the rear side of the solar cell is connected in an electrically conductive manner only to at least one of the rear-side metallization (6) or to the second doped region.

21. Method according to claim 20, wherein on the rear side of the solar cell, a doped region of the second conductivity type is constructed along the rear-side section boundary.

22. Method according to claim 21, wherein on the rear side of the solar cell, the rear side is covered with an insulating layer along the rear-side section boundary and outside of a rear-side contact face.

23. Method according to claim 20, wherein in a step b-1, holes are generated in the solar cell, with the holes extending essentially perpendicular to the front side of the solar cell.

24. Method according to claim 23, wherein in step b-4, a doped region of the first conductivity type is also generated on the hole walls and the third doped region is arranged in a region of the holes, such that the first doped region and third doped region are connected to each other electrically via the doped region on the hole walls.

25. Method according to claim 20, wherein before step b-4, a diffusion barrier is deposited on the rear side of the solar cell.

26. Method according to claim 25, wherein the doped regions diffused in step b-4 at least one of on the rear side or the front side of the solar cell are electrically isolated by a laser.
